(19) United States
(12) Patent Application Publication
(10) Pub. No.: US 2009/0061755 A1
(43) Pub. Date: Mar. 5, 2009

(54) Intake Duct

(75) Inventors: Andrew R. Calder, New Lenox, IL (US); Andrew J. Stroede, Frankfort, IL (US); Brendan F. Doorhy, Westmont, IL (US); Rhonda Johnson, Chicago Heights, IL (US); Alva B. Eaton, Nottingham Park, IL (US); Elsa V. Madrigal, Chicago, IL (US); Darryl S. Benson, Crystal Lake, IL (US); Charles T. Newcomb, Naperville, IL (US); James N. Fleming, Naperville, IL (US); Lorne Turrentine, Chicago, IL (US)

Correspondence Address: PANDUIT CORP., LEGAL DEPARTMENT - TP12, 17301 SOUTH RIDGELAND AVENUE, TINLEY PARK, IL, 60477, US

(73) Assignee: PANDUIT CORP., Tinley Park, IL (US)

(21) Appl. No.: 12/198,934

(22) Filed: Aug. 27, 2008

Related U.S. Application Data
(60) Provisional application No. 60/968,425, filed on Aug. 28, 2007.

(51) Int. Cl. H05K 5/00; H05K 7/20

(52) U.S. Cl. 454/184; 361/692

(57) ABSTRACT

An electronic equipment cabinet having a duct positioned in a side portion of the cabinet. The duct has a first opening formed in a bottom wall of the duct and a second opening formed in an inside wall of the duct. The first opening is configured to generally align with a cool air source and receive cool air from the cool air source with the first duct installed in the cabinet. The second opening is in fluid communication with a front internal portion of the cabinet and is configured to direct cool air from the duct to the front internal portion of the cabinet with the duct installed in the cabinet.

### CROSS-REFERENCE TO RELATED APPLICATIONS

This application claims priority to U.S. Provisional Patent Application No. 60/968,425, filed Aug. 28. 2007.

### FIELD OF INVENTION

This invention relates to systems and methods for cooling electronic equipment in equipment cabinets. In particular, the invention relates to intake ducts for directing cooled air through equipment cabinets for cooling electronic equipment.

### BACKGROUND

In a typical data center equipments cabinets are used to hold various types of electronic equipment such as servers and other mission-critical data-processing equipment. When in use, the electronic equipment housed in the cabinets generates heat that must be extracted or damage to the equipment can result. As equipment densities in the cabinets increase, so do the heat extraction (cooling) needs. Today, in a typical data center, it is not unusual for electronic equipment to generate 10 kilowatts and beyond of heat per cabinet (typical range 2 to 20 kilowatts per cabinet).

Currently, one method for cooling the electronic equipment in a data center is the use of the “hot aisle/cold aisle” concept; that is cool, conditioned air flows underneath a raised floor and enters the room through perforated floor tiles. The perforated tiles are strategically placed in front of the cabinets (thus creating the “cold aisle”) such that the cool air can be pulled into the cabinets, through a perforated door, to cool the equipment. The cool air picks up heat as it is drawn through the equipment by fans and then the warm air exits the back of the cabinet through another perforated door into the “hot aisle.” The exiting warm air is eventually drawn back into the room air conditioners and the cooling cycle repeats.

Although it is reasonably effective, the hot aisle/cold aisle method of cooling electronic equipment can be very inefficient and has various drawbacks. For example, warm air that exits the cabinet into the hot aisle can be drawn back to the cold aisle via the action of the equipment fans and normal room air circulation. In addition, the perforated floor tiles must be carefully placed and sized to effectively cool the equipment. If equipment is added or changed, or if a tile is accidentally moved or covered up, inefficient cooling results and cooling must be increased. Finally, since the flow of cool air is not directed to the equipment that needs cooling any change in the room configuration or even people standing in the aisles can disrupt the cool air flow. These disruptions result in a smaller portion of the cool air actually cooling the equipment, which further decreases efficiency. The inefficiencies of the hot aisle/cold aisle system lead to wasted energy (e.g. electricity to power the air conditioners), due to the need to “overcool” the data center to make up for cooling losses. In addition, data loss and downtime can result due to equipment damage from overheating.

Therefore, there is a need for a system and method for cooling electronic equipment in a cabinet that efficiently and effectively delivers cooled air where it is needed, with no warm air mixing. It would also be beneficial to eliminate the dependence on a cold aisle for cool air delivery, for example by sending the cooled air directly into the cabinet.

### SUMMARY

In one example, an electronic equipment cabinet is provided comprising a first duct positioned in a side portion of the electronic equipment cabinet. The first duct has a first opening formed in a bottom wall of the duct and a second opening formed in an inside wall of the duct. The first opening is configured to generally align with a cool air source and receive cool air from the cool air source with the duct installed in the cabinet. The second opening is in fluid communication with a front internal portion of the cabinet and is configured to direct cool air from the duct to the front internal portion of the cabinet with the first duct installed in the cabinet.

In another example, an electronic equipment cabinet is provided comprising a duct positioned in a side portion of the electronic equipment cabinet. The duct has an intake opening formed in a bottom wall of the duct and a plurality of exhaust openings formed in an inside wall of the duct. The intake opening is configured to generally align with a cool air source and receive cool air from the cool air source with the duct installed in the cabinet. The plurality of exhaust openings are configured to generally align with intake vents of electronic equipment installed in the cabinet and to direct cool air from the duct to the side intake vents of the electronic equipment with the duct installed in the cabinet.

In another example, an intake duct system for an electronic equipment cabinet is provided comprising a first duct configured for installation in a side portion of the cabinet. The duct has a first opening formed in a bottom wall of the duct and a second opening formed in an inside wall of the duct. The first opening is configured to generally align with a cool air source and receive cool air from the cool air source with the duct installed in the cabinet and the second opening is in fluid communication with a front internal portion of the cabinet and is configured to direct cool air from the duct to the front internal portion with the duct installed in the cabinet.

In another example, an intake duct system for an electronic equipment cabinet is provided comprising a duct configured for installation in a side portion of the electronic equipment cabinet. The duct has an intake opening formed in a bottom wall of the duct and a plurality of exhaust openings formed in an inside wall of the duct. The intake opening is configured to generally align with a cool air source and receive cool air from the cool air source with the duct installed in the cabinet and the plurality of exhaust openings are configured to generally align with intake vents of electronic equipment installed in the cabinet and to direct cool air from the duct to the side intake vents with the duct installed in the cabinet.

### BRIEF DESCRIPTION OF THE DRAWINGS

Certain examples of the present invention are illustrated by the accompanying figures. It should be understood that the figures are not necessarily to scale and that details that are not necessary for an understanding of the invention or that render other details difficult to perceive may be omitted. It should be understood, of course that the invention is not necessarily limited to the particular examples illustrated herein.

FIG. 1 is a perspective view of one example of an intake duct;

FIG. 2 is the intake duct of FIG. 1 with the inside wall removed;

FIG. 3 is an enlarged partial view of FIG. 1:

FIG. 4 is the intake duct of FIG. 2 showing an example of air flow through the intake duct;

FIG. 5 is a front perspective view of one example of an intake duct installed in an electronic equipment cabinet with the front door and side panel removed;

FIG. 6 is a side perspective view of the installed intake duct of FIG. 5:

FIG. 7 is the intake duct of FIG. 6 with the front wall and outside wall in phantom:

FIG. 8 is a side perspective view of one example of a center duct;

FIG. 9 is a front perspective view of the center duct of FIG. 8 installed in an electronic cabinet with the doors and side panels removed;

FIG. 10 is a rear perspective view of the installed center duct of FIG. 9:

FIG. 11 is a side view of the installed center duct of FIG. 9;

FIG. 12 is a front perspective view of a second example of an intake duct;

FIG. 13 is a rear perspective view of the intake duct of FIG. 12:

FIG. 14 is a side perspective view of the intake duct of FIGS. 12 and 13 installed in an electronic equipment cabinet with the doors and side walls removed:

FIG. 15 is a side view of the installed intake vent of FIG. 14 showing an example of air flow through the intake duct; and

FIG. 16 is a side perspective view of the installed intake vent of FIG. 14 with an adjacent ganged electronic equipment cabinet.

### DETAILED DESCRIPTION

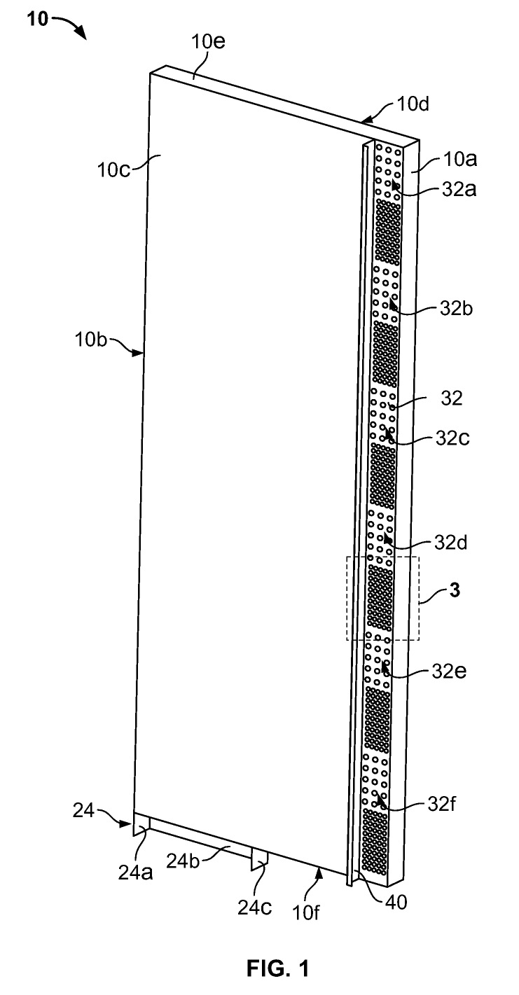

Referring to FIGS. 1-3, one example of an intake duct 10 is shown. In this example, intake duct 10 is generally rectangular and is formed by front wall 11A, back wall 10B, inside wall 10C, outside wall 10D, top wall 10E, and bottom wall 10F. As used herein, inside wall 10C is the wall of intake duct 10 that faces the electronic equipment in the interior of a cabinet when intake duct 10 is installed and front wall 10A is the wall of intake duct 10 that faces the front of the cabinet when intake duct 10 is installed. Although the exemplary intake duct 10 is described herein as being generally rectangular, intake duct 10 could be made of any shape or size required for a particular application or to fit a particular equipment cabinet. In the example shown herein, intake duct 10 is approximately 20 inches×4.5 inches×84 inches.

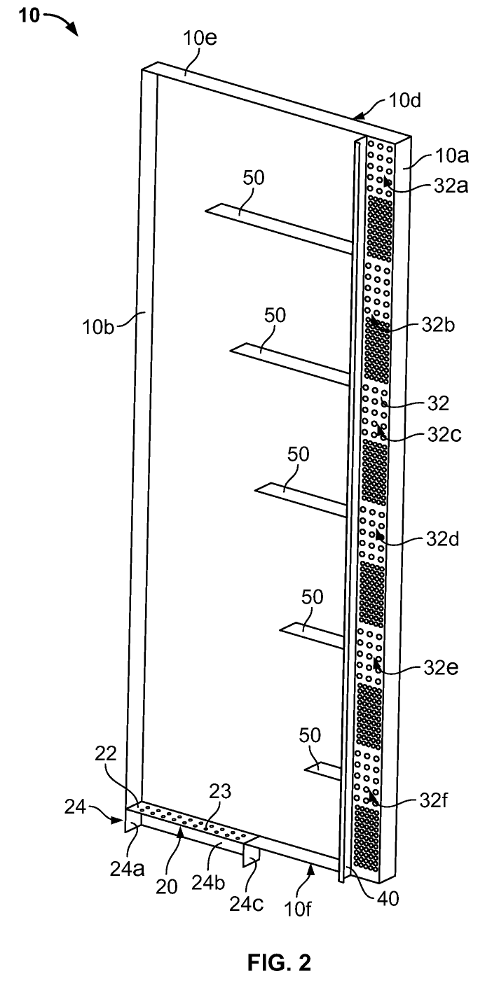

Opening 20 (see FIG. 2) is formed in bottom wall 10F and is positioned such that opening 20 will be aligned with a perforated floor cutout when duct 10 is installed in a cabinet. Extension member 24, which in this example is formed by three vertical walls 24A-C, extends from bottom wall 10F and surrounds opening 20 to assist in directing cool air from the perforated floor tile to opening 20. As show in FIGS. 1 and 2, when opening 20 is positioned at the back of duct 10, first wall 24A of extension member 24 can be an extension of back wall 10B and second wall 24B can be an extension of outside wall 10D. When installed, opening 20 and extension member 24 provide an inlet into duct 10 for cooled air flowing from the perforated floor cutout, which allows a typical perforated front cabinet door to be replaced by a solid door, if desired, and allows the flow of cool air from under the floor to enter duct 10.

In the example shown, perforated intake panel 22, having multiple holes 23, is positioned over opening 20 to deliver more uniform air flow to duct 10. Holes 23 are formed in intake panel 22 such that intake panel 22 is approximately 56% open. In some instances, it has been found that wide-open inlets may not provide consistent airflow into duct 10 (e.g. the air entering duct 10 will try to take the path of least resistance, so some areas will receive more cool air and be overcooled while others will not receive enough cool air and will be starved). The use of intake panel 22 has been shown to provide more uniform air flow over the entire area of opening 20 by converting high velocity, low pressure air into low velocity, high pressure air. Alternatively, if uniform air flow through the duct is not a problem or concern in a particular application, intake panel 22 can be removed.

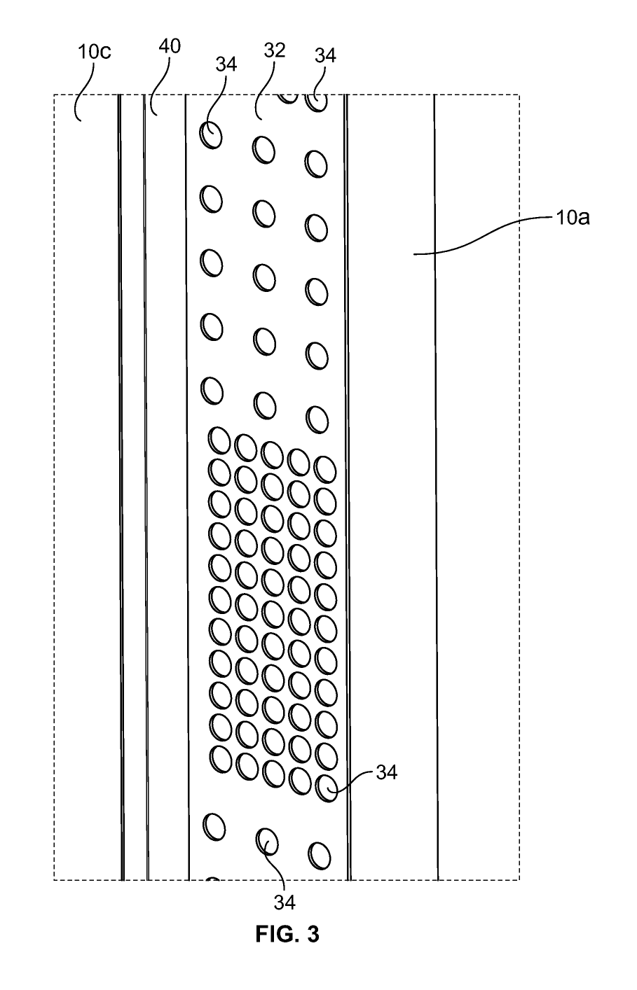

An opening is also formed in inside wall 10C and in the example shown extends the entire height of inside wall 10C and back a predetermined distance from front wall 10A. The opening in inside wall 10C provides an exhaust for cool air out of duct 10 and directs the cool air flowing through duct 10 towards the front of the electronic equipment mounted in the cabinet. In the example shown, perforated exhaust panel 32, having multiple holes 34, is positioned over the opening in inside wall 10C to more uniformly disperse the cool air flowing out of duct 10. Holes 34 in exhaust panel 32 are formed in exhaust panel 32 such that six sections 32A-F are defined in exhaust panel 32. As can best be seen in FIGS. 2 and 3, holes 34 are patterned such that each section 32A-F has an upper portion that is approximately 30% open and a lower portion that is approximately 36% open. In some instances, it has been found that a wide-open exhaust draws too much air in some areas of the exhaust, while causing starvation in other areas. The use of exhaust panel 32 more uniformly disperses the cool air as it leaves duct 10 to enter the area in front of the electronic equipment. Alternatively, if uniform air flow out of the duct is not a problem or concern in a particular application, exhaust panel 32 can be removed.

In the example shown, to further assist in providing uniform air flow from duct 10 across the front of the electronic equipment deflector 40 extends from inside wall 10C along the edge of the opening in inside wall 10C. Deflector 40 is generally L-shaped, extends the entire height of inside wall 10C, and is used to force all air to the front of the server equipment and prevent cool air from flowing past the face of the electronic equipment by disrupting the cool air flowing from exhaust panel 32, thus providing more uniform air flow across the entire front of the electronic equipment. Again, if uniform air flow across the front of the electronic equipment is not a problem or concern in a particular application, deflector 40 can be removed.

As can be seen in FIG. 2, in this example, baffles 50 are also positioned in the interior of duct 10 and extend horizontally through duct 10 between outside wall 10D, front wall 10A, and inside wall 10C. As shown herein, there are five baffles 50, each baffle being positioned near the bottom of one of the defined sections 32A-F of exhaust panel 32. Each baffle 50 has a different length, with the length of the baffles 50 increasing the higher the position in duct 10 or the further away the baffle 50 is from intake panel 22. In some instances, it has been found that completely open ducts result in more cool air exiting at the top of the duct (e.g. from the momentum of the air driving it to the top of the duct), thereby starving the lower sections of the duct. Baffles 50 can be used to control the direction, velocity and pressure of the cool air flow by breaking up the vertical air flow and directing the air flow sideways towards the front of the duct 10. Alternatively, if the flow of cool air through the duct is not a problem or concern in a particular application, baffles 50 can be removed.

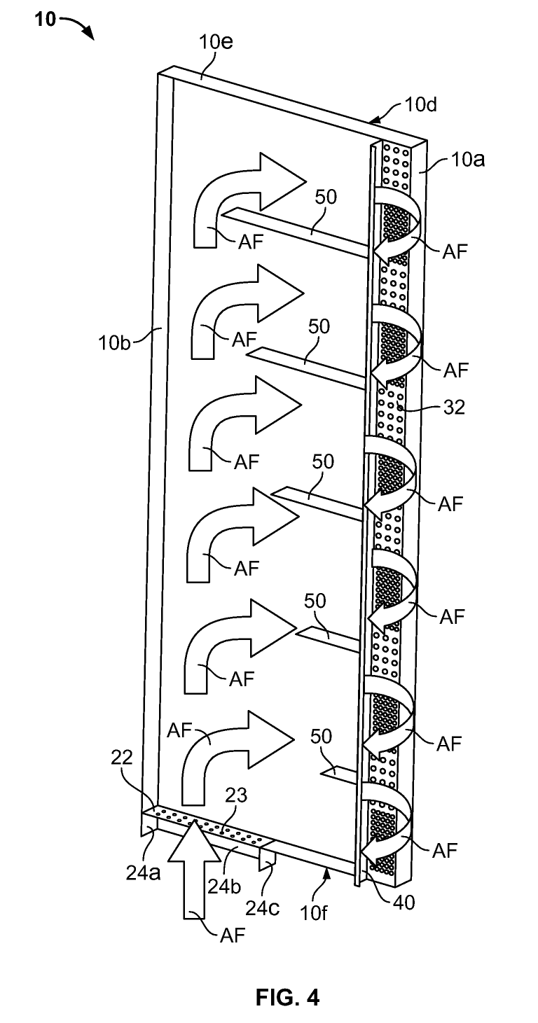

Referring to FIG. 4, exemplary air flow, shown by arrows AF, through the intake duct 10 of FIGS. 1-3 is shown. As can be seen, cool air from a perforated or open floor cutout flows through extension member 24 to intake panel 22. As the cool air flows through holes 23 in intake panel 22, the cool air is disrupted and uniformly flows into duct 10. The cool air then flows from intake panel 22 through duct 10 where portions of the cool air flow are redirected by baffles 50 towards the different sections 32A-F of exhaust panel 32. As the cool air flows through holes 34 in exhaust panel 32, the cool air is against disrupted to provide a more uniform flow of air out of duct 10. The cool air exiting exhaust panel 32 finally passes over deflector 40, which further disrupts the cool air flow, thereby preventing the cool air from flowing past the front of the electronic equipment and providing uniform distribution exclusively to the front of the electronic equipment.

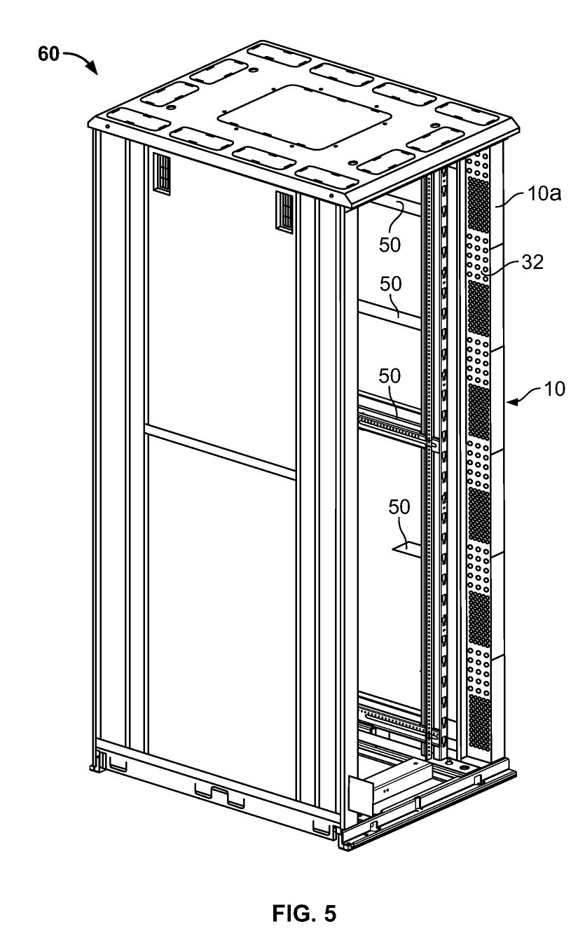

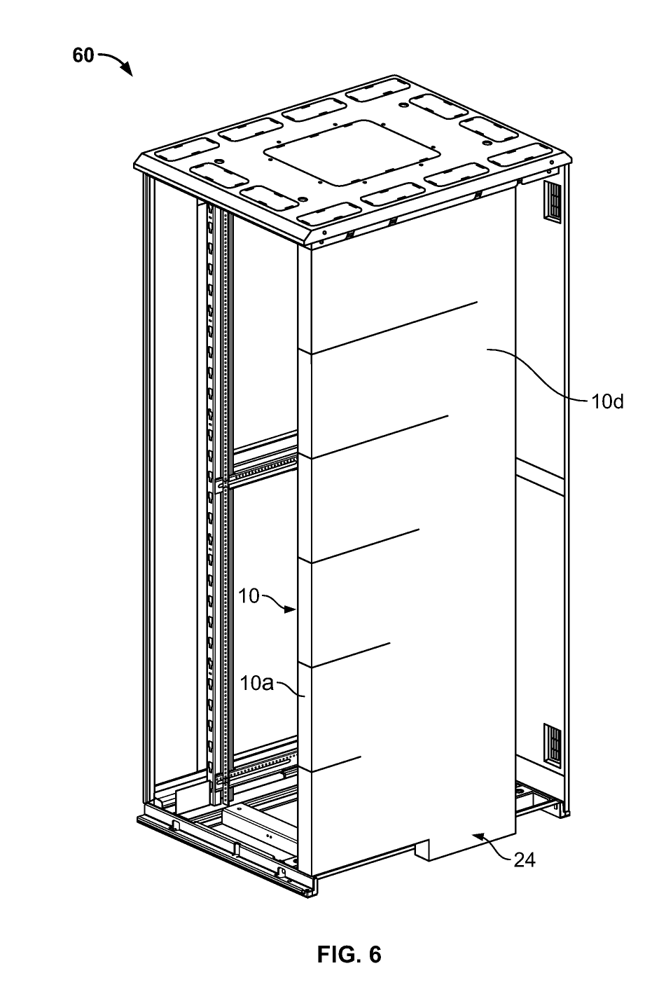

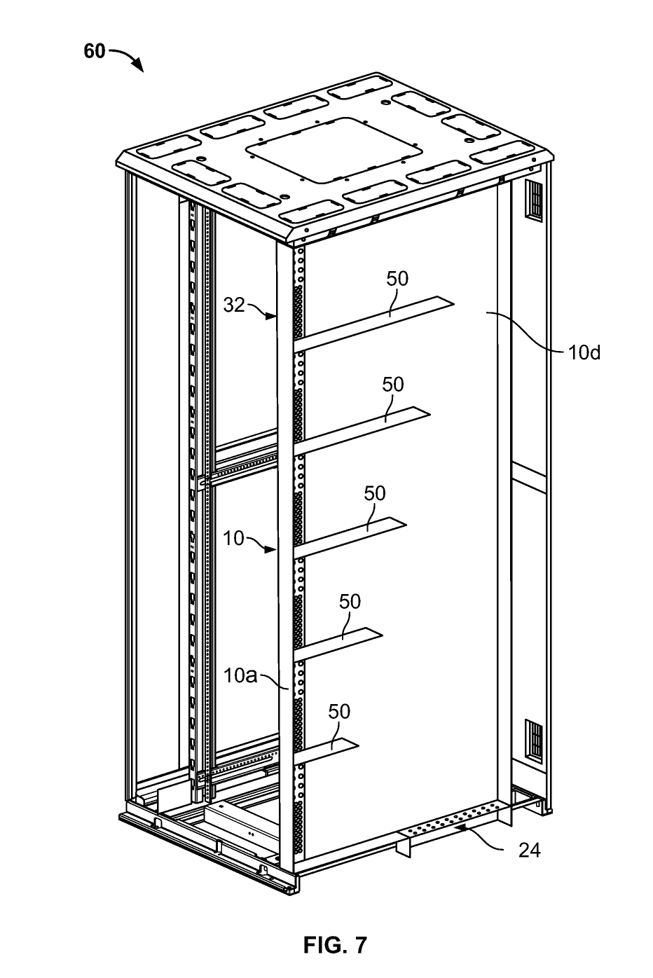

Referring now to FIGS. 5-7, the exemplary intake duct 10 of FIGS. 1-4 is shown installed in an electronic equipment cabinet 60 (in FIGS. 5-7 the front door and right side panel of cabinet 60 are removed for clarity). As shown in FIGS. 5-7 and described herein, cabinet 60 is a network cabinet, such as that shown and described in co-pending U.S. patent application Ser. No. 11/467,956. 11/538,884, 11/559,708, 11/623,358, 11/623,839, and 11/683,052, which are incorporated herein by reference. However, it will be understood that intake duct 10 can be used with any type of cabinet that is adapted to carry electronic equipment, such as servers. In addition to having a single intake duct 10 installed in cabinet 60 as shown in FIGS. 5-7, two ducts 10 could also be installed, one on each side of cabinet 60 (the ducts 10 would be mirror images of each other) depending on the cooling requirements of the particular cabinet.

The exemplary intake duct 10 described above provides cool air, in the proper location, with no mixing of warm air from a hot aisle through the locating, sizing, and shaping of duct 10, as well as the strategic placement of baffles 50 to control air direction, pressure and velocity. It has been demonstrated that the use of exemplary duct 10 described above can increase cool air utilization efficiency by 50% by limiting the flow of cool air to only the air spaces within the cabinet (e.g. the ducts and the front of the equipment), thus reducing the volume of cold air required, which increases efficiency of the cold air delivery method. This increased efficiency allows the data center cooling to be “dialed back,” or existing capacity can be used to cool more equipment (e.g. higher density). In addition, data center “over cooling” to overcome inefficient cool-air delivery can be reduced.

Some additional benefits that may be realized through use of the exemplary intake duct 10 are: provides all of the cool air required by the cabinet, not just supplemental air to add to hot/cold aisle air; the ability to use a solid front door on the cabinet instead of a perforated door, which prevents unwanted air from entering the cabinet; the delivery of cool air along the full height of the cabinet, not just top or bottom; reduction of air usage (as measured in cfm) by 25-50%; reduced energy costs; reduction of the number of perforated floor tiles required; direction of the cool air to the front of the cabinet where it is needed most; and providing a system that requires no adjustment.

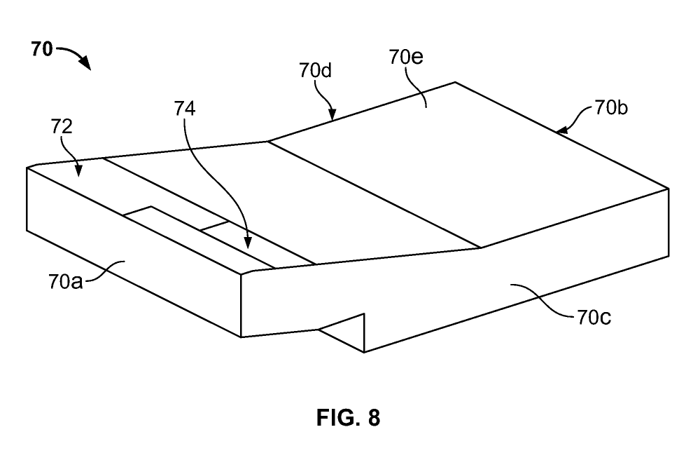

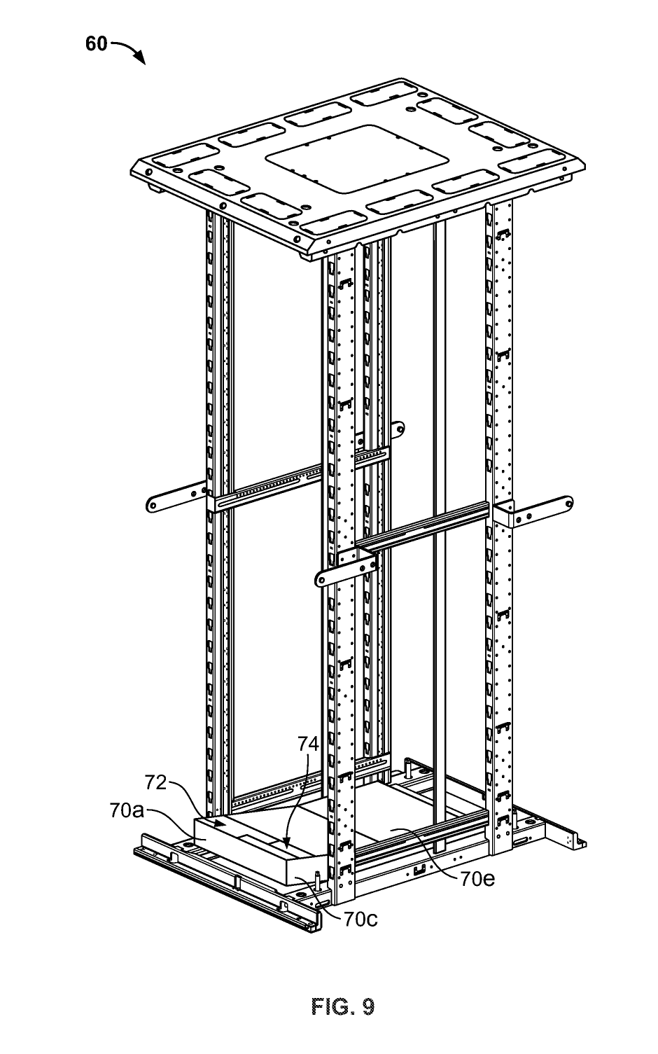

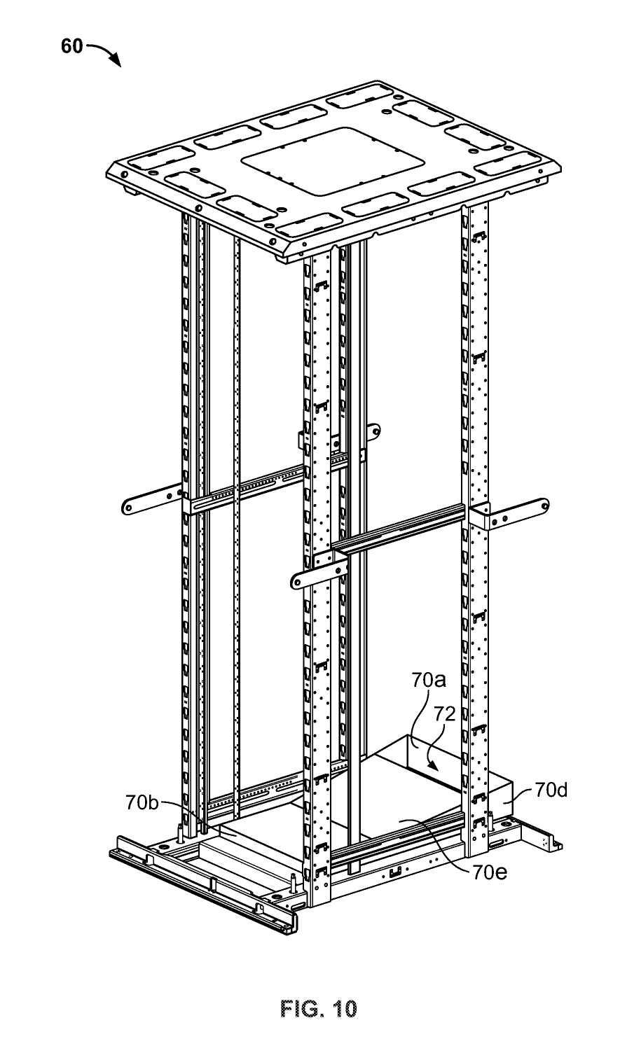

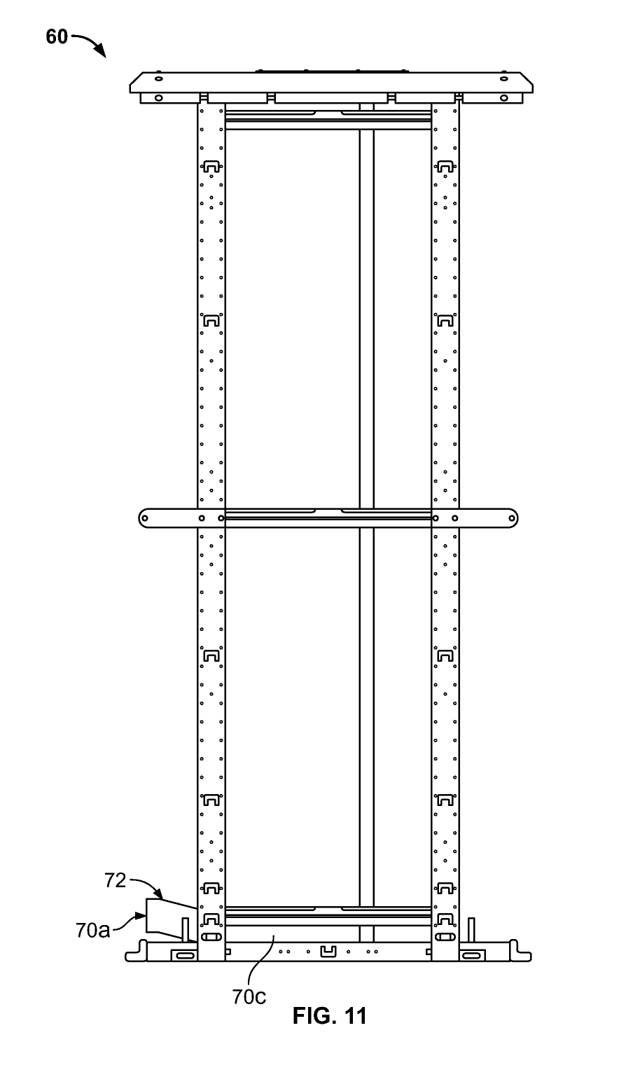

Referring to FIGS. 8-11, one example of a center duct 70 is shown. Center duct 70 can be used on its own to provide cool air received from a perforated or open floor cutout to the front of the cabinet or can be used with one or more intake ducts 10. In the example shown, center duct 70 is generally rectangular and is formed by front wall 70A, back wall 70B, side walls 70C and 70D, and top wall 70E. As can best be seen in FIG. 8, in this example front wall 70A has a general stair step configuration formed by two vertical walls and an interconnecting generally horizontal wall. As can be seen in FIGS. 9 and 11, this configuration of front wall 70A allows center duct 70 to be placed in the center of cabinet 60 and to extend over the side to side base beam of the base member of cabinet 60. Although the exemplary center duct 70 is described herein as being generally rectangular, center duct 70 could be made of any shape or size required for a particular application or to fit a particular equipment cabinet. In the example shown herein, center duct 70 is approximately 24 inches×19 inches×4 inches.

The bottom of center duct 70 is left open such that front wall 70A, back wall 70B and side walls 70C and 70D define opening 74, which will be aligned with a perforated or open floor cutout when center duct 70 is installed in a cabinet. Opening 74 provides an inlet into center duct 70 for cooled air flowing from the perforated or open floor cutout, which allows a typical perforated front cabinet door to be replaced by a solid door, if desired, and allows the flow of cool air from under the floor to enter center duct 70. In this example, the perforations are formed in the intake panel over opening 74 such that the intake panel is approximately 56% open. Alternatively, if uniform air flow and/or pressure regulation of the air flowing through center duct 70 is not a problem or concern in a particular application the intake panel can be removed.

Opening 72 is formed in top wall 70E and in the example shown extends the entire width of top wall 70E and back a predetermined distance from front wall 70A. Opening 72 provides an exhaust for cool air out of center duct 70 and directs the cool air flowing through center duct 70 towards the front of the electronic equipment mounted in the cabinet.

Cool air from a perforated or open floor cutout flows into center duct 70 through opening 74. The cool air then flows from opening 74 through duct 70 and exhausts through opening 72.

Referring specifically to FIGS. 9-11, the exemplary center duct 70 of FIG. 8 is shown installed in an electronic equipment cabinet 60 (in FIGS. 9-11 the front and back doors door and side panels of cabinet 60 are removed for clarity). As shown in FIGS. 9-11 and described herein, cabinet 60 is a network cabinet, such as that shown and described in co-pending U.S. patent application Ser. No. 11/467,956, 11/538,884, 11/559,708, 11/623,358, 11/623,839, and 11/683,052, which are incorporated herein by reference. However, it will be understood that center duct 70 can be used with any type of cabinet that is adapted to carry electronic equipment, such as servers. In addition to having center duct 70 installed in cabinet 60 as shown in FIGS. 9-11, one or two intake ducts 10 could also be installed, one on each side of cabinet 60 (the ducts 10 would be mirror images of each other) depending on the cooling requirements of the particular cabinet.

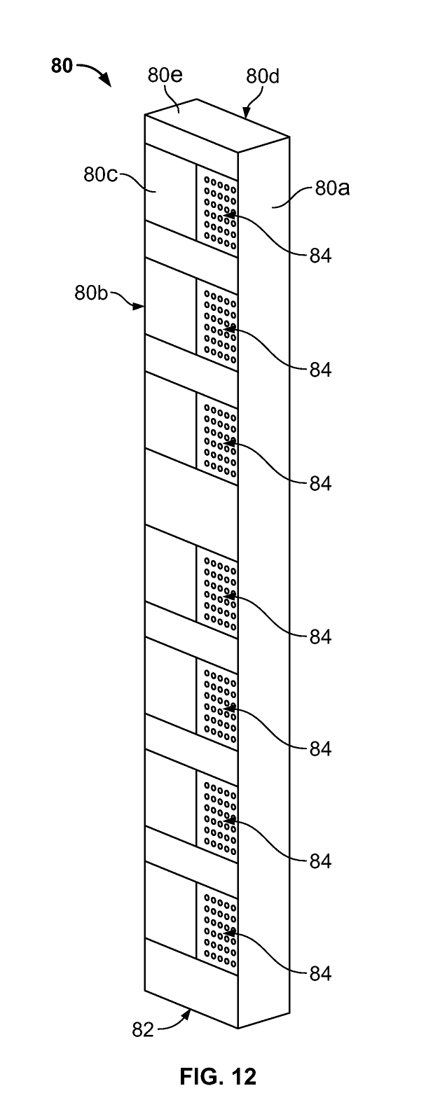

Referring to FIGS. 12-16 a second example of an intake duct 80 is shown, which can be used with electronic equipment 110 having side to side air flow, such as switches. In this example, intake duct 80 is generally rectangular and is formed by front wall 80A, back wall 80B, inside wall 80C, outside wall 80D, and top wall 80E. As used herein, inside wall 80C is the wall of intake duct 80 that faces electronic equipment 110 when intake duct 80 is installed and front wall 80A is the wall of intake duct 80 that faces the front of the cabinet when intake duct 80 is installed. Although intake duct 80 is described herein as being generally rectangular, it could be made of any shape or size required for a particular application or to fit a particular equipment cabinet. In the example shown herein, intake duct 80 is approximately 84 inches×19 inches×4 inches.

The bottom of intake duct 80 is left open such that front wall 80A, back wall 80B and side walls 80C and 80D define opening 82, which will be generally aligned with a perforated or open floor cutout when intake duct 80 is installed in a cabinet. Opening 82 provides an inlet into intake duct 80 for cooled air flowing from the perforated or open floor cutout, which allows a typical perforated front cabinet door to be replaced by a solid door, if desired, and allows the flow of cool air from under the floor to enter intake duct 80. Similar to that described above, a perforated intake panel (not shown) can be positioned over opening 82 to deliver more uniform air flow and pressure to intake duct 80. In this example, the perforations are formed in the intake panel such that the intake panel is approximately 56% open. Alternatively, if uniform air flow and/or pressure regulation of the air flowing through intake duct 80 is not a problem or concern in a particular application, the intake panel can be removed.

Multiple openings 84 are formed in inside wall 80C and are positioned such that openings 84 will generally align with the intake vents in electronic equipment 110. Openings 84 in inside wall 80C provide an exhaust for cool air out of intake duct 80 and direct the cool air flowing through duct 80 towards the intakes of electronic equipment 110 in the cabinet.

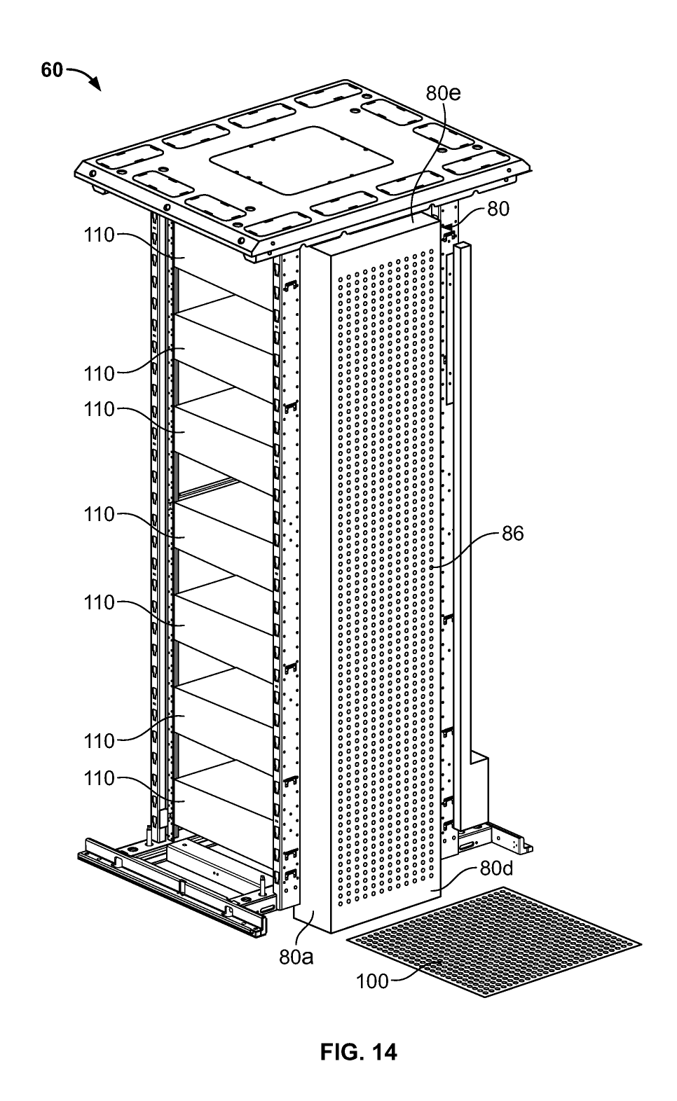

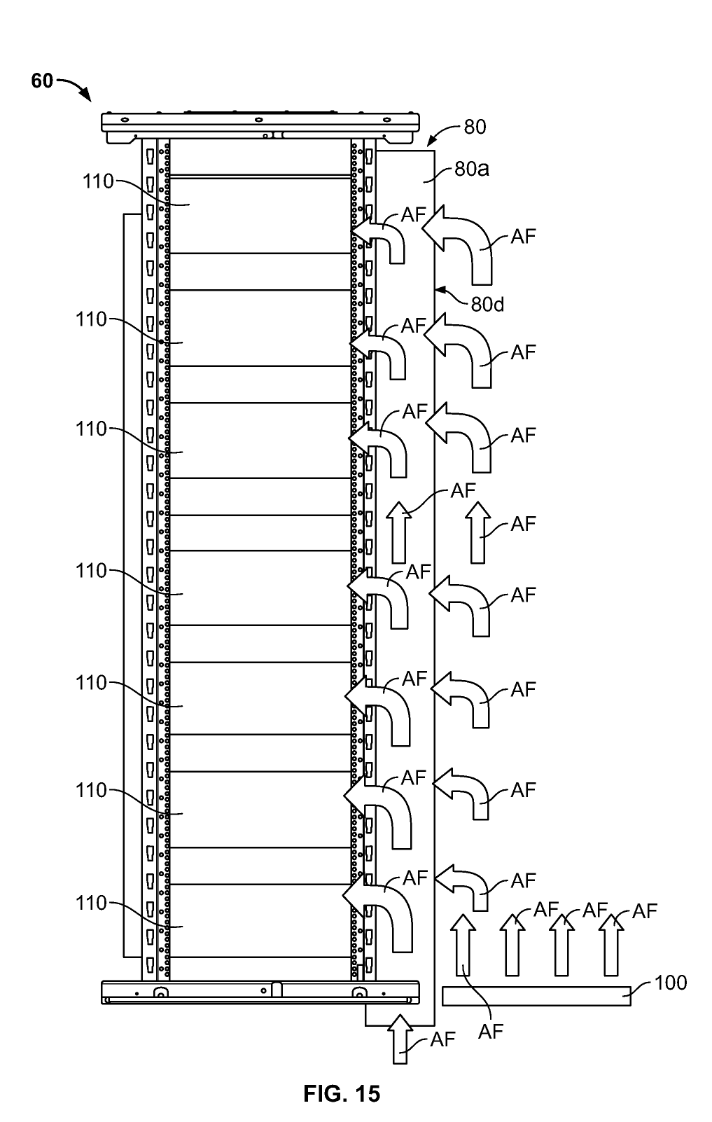

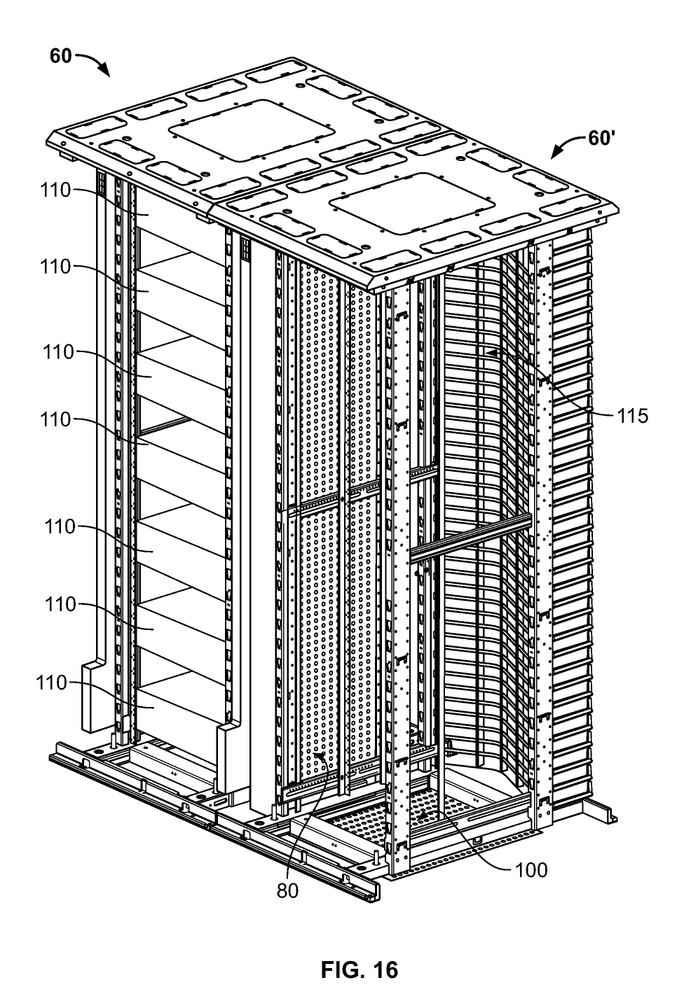

In addition to receiving cool air through opening 82, the example shown also includes perforations 86 formed in outside wall 80D, which allows intake duct 80 to receive supplemental cool air from cool air sources adjacent to the cabinet. In this example, perforations 86 are approximately 56% open. Perforations 86 can be used in various situations, such as when there is a perforated floor tile 100 adjacent to the cabinet (see FIGS. 14 and 15) or when the cabinet is ganged to another cabinet and the other cabinet does not contain heat generating electrical equipment, such as patch panels (see FIG. 16). In these situations, cool air that would otherwise be exhausted into the room from the adjacent floor tile 100 or cool air that is supplied to the adjacent cabinet that does not require cool air, can be supplied to intake duct 80 through perforations 86 to supplement the cool air received from opening 82. In the example shown, perforations 86 cover approximately the entire outside wall 80D. However, perforations 86 could be configured to cover any portion of outside wall 80D required. For example, if electronic equipment 110 in the upper half of the cabinet is not receiving sufficient cooling air, outside wall 80D could be perforated on the upper half to provide supplemental cool air to the electronic equipment 110 in the upper half of the cabinet. Alternatively, if opening 82 is providing sufficient cooling air for a particular application, outside wall 80D could be a solid panel with no perforations.

Referring to FIG. 15, exemplary air flow, shown by arrows AF, from the perforated or open floor cutout underneath intake duct 80 and from adjacent perforated floor tile 100 and into and through intake duct 80 of FIGS. 12-14 is shown. As can be seen, cool air from the perforated or open floor cutout underneath duct 80 flows through opening 82 into duct 80 and out openings 84. In addition, cool air from perforated floor cutout 100 flows through perforations 86 in outside wall 80D into duct 80 and out openings 84.

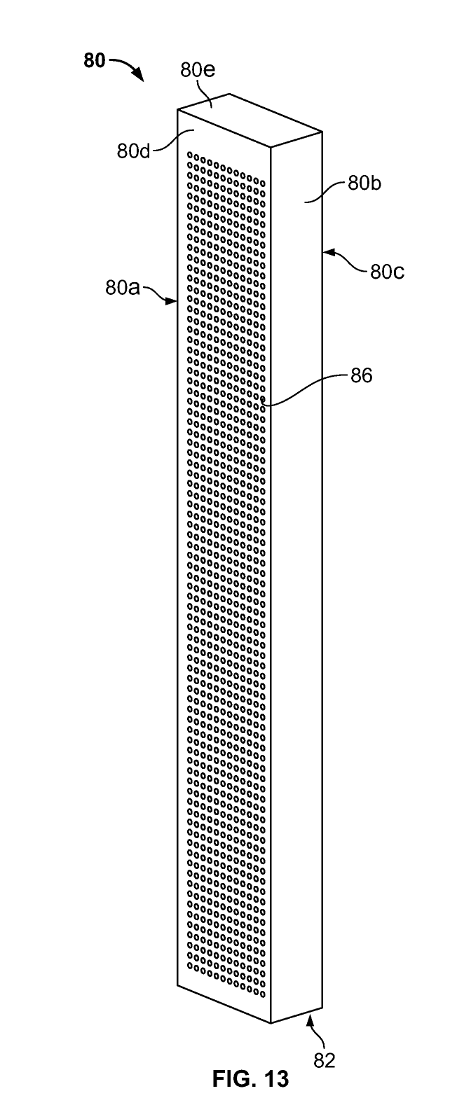

Referring to FIGS. 14 and 15, exemplary intake duct 80 of FIGS. 12 and 13 is shown installed in an electronic equipment cabinet 60 (in FIGS. 14-16 the front and rear doors and side panels of cabinet 60 are removed for clarity) having an adjacent perforated floor tile 100. As shown in FIGS. 14 and 15 and described herein, cabinet 60 is a network cabinet, such as that shown and described in co-pending U.S. patent application Ser. No. 11/467,956, 11/538,884, 11/559,708, 11/623,358, 11/623,839, and 11/683,052, which are incorporated herein by reference. However, it will be understood that intake duct 80 can be used with any type of cabinet that is adapted to carry electronic equipment with side to side air flow.

Referring to FIG. 16, exemplary intake duct 80 of FIGS. 12-15 is shown installed in an electronic equipment cabinet 60, which is adjacent to a second electronic equipment cabinet 60′. Electronic equipment 110, which is heat generating and has side to side air flow, is installed in cabinet 60 and non-heat generating electronic equipment 115, such as patch panels, is installed in cabinet 60′. Perforated floor tile 100 is positioned beneath cabinet 60′ and provides cool air to cabinet 60′. In this type of installation, intake duct 80 will receive cool air from a perforated floor tile beneath cabinet 60 through opening 82 and direct the cool air to the intakes of electronic equipment 110. In addition, cool air will be supplied to cabinet 60′ through perforated floor tile 100. Since the electronic equipment 115 in cabinet 60′ does not generate heat and does not require cooling, intake duct 80 will also receive cool air from cabinet 60′ through perforations 86 in back wall 80B and direct the cool air to the intakes of electronic equipment 110.

We claim:

1. An electronic equipment cabinet, comprising:
a first duct positioned in a side portion of the electronic equipment cabinet, the first duct comprising a first opening formed in a bottom wall of the first duct and a second opening formed in an inside wall of the first duct; wherein
the first opening is configured to generally align with a cool air source and receive cool air from the cool air source with the first duct installed in the electronic equipment cabinet; and
the second opening is in fluid communication with a front internal portion of the electronic equipment cabinet and is configured to direct cool air from the first duct to the front internal portion of the electronic equipment cabinet with the first duct installed in the electronic equipment cabinet.

2. The electronic equipment cabinet of claim 1, further comprising a perforated intake panel positioned over the first opening.

3. The electronic equipment cabinet of claim 1, further comprising a perforated exhaust panel positioned over the second opening.

4. The electronic equipment cabinet of claim 1, wherein the first duct comprises a plurality of baffles positioned within the first duct and configured to direct air from the first opening to the second opening.

5. The electronic equipment cabinet of claim 1, wherein the first duct comprises a deflector extending from the inside wall adjacent the second opening, the deflector configured to disrupt air flowing from the second opening to the front portion of the electronic equipment cabinet.

6. The electronic equipment cabinet of claim 1, further comprising:
a second duct positioned in a second side portion of the electronic equipment cabinet, opposite the first side portion, the second duct comprising a third opening formed in a bottom wall of the second duct and a fourth opening formed in an inside wall of the second duct;
wherein
the third opening is configured to generally align with a second cool air source and receive cool air from the second cool air source with the second duct installed in the electronic equipment cabinet; and
the fourth opening is in fluid communication with the front internal portion of the electronic equipment cabinet and is configured to direct cool air from the second duct to the front internal portion of the electronic equipment cabinet with the second duct installed in the electronic equipment cabinet.

7. The electronic equipment cabinet of claim 1, further comprising:
a center duct positioned in a bottom portion of the electronic equipment cabinet, the center duct comprising a third opening formed in a bottom wall of the center duct and a fourth opening formed in a top wall of the center duct: wherein
the third opening is configured to generally align with a second cool air source and receive cool air from the second cool air source with the center duct installed in the electronic equipment cabinet; and
the fourth opening is in fluid communication with the front internal portion of the electronic equipment cabinet and is configured to direct cool air from the center duct to the front portion of the electronic equipment cabinet with the center duct installed in the electronic equipment cabinet.

8. An electronic equipment cabinet, comprising:
a duct positioned in a side portion of the electronic equipment cabinet, the duct comprising an intake opening formed in a bottom wall of the duct and a plurality of exhaust openings formed in an inside wall of the duct; wherein
the intake opening is configured to generally align with a cool air source and receive cool air from the cool air source with the duct installed in the electronic equipment cabinet; and
the plurality of exhaust openings are configured to generally align with intake vents of electronic equipment installed in the electronic equipment cabinet and to direct cool air from the duct to the side intake vents of the electronic equipment with the duct installed in the electronic equipment cabinet.

9. The electronic equipment cabinet of claim 8, further comprising a perforated intake panel positioned over the intake opening.

10. The electronic equipment cabinet of claim 8, wherein the duct further comprising a plurality of perforations formed in an outer wall of the duct.

11. An intake duct system for an electronic equipment cabinet, comprising:
a first duct configured for installation in a side portion of the electronic equipment cabinet, the first duct comprising a first opening formed in a bottom wall of the first duct and a second opening formed in am inside wall of the first duct; wherein
the first opening is configured to generally align with a cool air source and receive cool air from the cool air source with the first duct installed in the electronic equipment cabinet; and
the second opening is in fluid communication with a front internal portion of the electronic equipment cabinet and is configured to direct cool air from the first duct to the front internal portion of the electronic equipment cabinet with the first duct installed in the electronic equipment cabinet.

12. The intake duct system of claim 11, further comprising a perforated intake panel positioned over the first opening.

13. The intake duct system of claim 11, wherein the second opening extends substantially an entire height of the inside wall.

14. The intake duct system of claim 13, further comprising a perforated exhaust panel positioned over the second opening.

15. The intake duct system of claim 14, wherein the perforated exhaust panel comprises multiple sections, each section comprising an upper portion and a lower portion, wherein the perforations in the upper and lower portions are configured to provide different amounts of air flow.

16. The intake duct system of claim 11, further comprising a plurality of baffles positioned within the first duct and configured to direct air from the first opening to the second opening.

17. The intake duct system of claim 16, wherein the baffles extend generally horizontally from a front wall of the first duct and a length of each baffle increases as the vertical position of the baffle increases.

18. The intake duct system of claim 11, further comprising a deflector extending from the inside wall of the first duct adjacent the second opening, the deflector configured to disrupt air flowing from the second opening to the front portion of the electronic equipment cabinet.

19. The intake duct system of claim 11, further comprising:
a center duct configured for installation in a bottom portion of the electronic equipment cabinet, the center duct comprising a third opening formed in a bottom wall of the center duct and a fourth opening formed in a top wall of the center duct: wherein
the third opening is configured to generally align with a second cool air source and receive cool air from the second cool air source with the center duct installed in the electronic equipment cabinet; and
the fourth opening is in fluid communication with the front portion of the electronic equipment cabinet and is configured to direct cool air from the center duct to the front portion of the electronic equipment cabinet with the center duct installed in the electronic equipment cabinet.

20. The intake duct system of claim 11, further comprising:
a second duct configured for installation in a second side portion of the electronic equipment cabinet, opposite the first side portion, the second duct comprising a third opening formed in a bottom wall of the second duct and a fourth opening formed in an inside wall of the second duct; wherein
the third opening is configured to generally align with a second cool air source and receive cool air from the second cool air source with the second duct installed in the electronic equipment cabinet; and
the fourth opening is in fluid communication with the front internal portion of the electronic equipment cabinet and is configured to direct cool air from the second duct to the front internal portion of the electronic equipment cabinet with the second duct installed in the electronic equipment cabinet.

21. The intake duct system of claim 20, further comprising:
a center duct configured for installation in a bottom portion of the electronic equipment cabinet, the center duct comprising a fifth opening formed in a bottom wall of the center duct and a sixth opening formed in a top wall of the center duct; wherein
the fifth opening is configured to generally align with a third cool air source and receive cool air from the third cool air source with the center duct installed in the electronic equipment cabinet; and
the sixth opening is in fluid communication with the front portion of the electronic equipment cabinet and is configured to direct cool air from the center duct to the front portion of the electronic equipment cabinet with the center duct installed in the electronic equipment cabinet.

22. An intake duct system for an electronic equipment cabinet, comprising:
a duct configured for installation in a side portion of the electronic equipment cabinet, the duct comprising an intake opening formed in a bottom wall of the duct and a plurality of exhaust openings formed in an inside wall of the duct; wherein
the intake opening is configured to generally align with a cool air source and receive cool air from the cool air source with the duct installed in the electronic equipment cabinet: and
the plurality of exhaust openings are configured to generally align with intake vents of electronic equipment installed in the electronic equipment cabinet and to direct cool air from the duct to the side intake vents of the electronic equipment with the duct installed in the electronic equipment cabinet.

23. The intake duct system of claim 22, wherein the duct extends substantially an entire height of the electronic equipment cabinet.

24. The intake duct system of claim 22, further comprising a perforated intake panel positioned over the intake opening.

25. The intake duct system of claim 22, wherein the exhaust openings comprise a plurality of perforations.

26. The intake duct system of claim 22, wherein the duct further comprises a plurality of perforations formed in an outer wall of the duct.
